(19) United States
(12) Patent Application Publication
(10) Pub. No.: US 2026/0286524 A1
(43) Pub. Date: Sep. 24, 2026

(54) SELECTIVE METAL-ON-METAL DEPOSITION PROCESS

(71) Applicant: ASM IP Holding B.V., Almere (NL)

(72) Inventors: Paul Ma, Scottsdale, AZ (US); Holger Saare, Leuven (BE)

(21) Appl. No.: 19/571,892

(22) Filed: Mar. 19, 2026

Related U.S. Application Data
(60) Provisional application No. 63/776,484, filed on Mar. 24, 2025.

(51) Int. Cl. C23C 16/455; C23C 16/04; C23C 16/44

(52) U.S. Cl. CPC C23C 16/45553; C23C 16/042; C23C 16/4408

(57) ABSTRACT

Methods of and reactor systems for selectively depositing a material on a surface of a substrate are disclosed. Exemplary methods include selectively treating a second surface to form a passivation layer on the second surface and selectively depositing metal material on a first surface to form selectively deposited metal.

### CROSS-REFERENCE TO RELATED APPLICATIONS

This application is a nonprovisional of, and claims priority to and the benefit of, U.S. Provisional Patent Application No. 63/776,484, filed Mar. 24, 2025 and entitled “SELECTIVE METAL-ON-METAL DEPOSITION PROCESS,” which is hereby incorporated by reference herein.

### FIELD OF INVENTION

The present disclosure relates generally to methods for selectively forming a material on a first surface on a substrate relative to a second surface on the substrate. More particularly, the disclosure relates to methods of selectively depositing material by selectively forming a passivation layer on a surface of the substrate.

### BACKGROUND OF THE DISCLOSURE

Metal or metallic films or layers are used for a wide variety of applications. For example, metal material films can be used to form conducting regions, barriers layers, or the like. Such metallic films can be used to form a variety of electronic devices, such as semiconductor devices, photovoltaic device, or the like.

In some device fabrication processes, it may be desirable to form a material only on certain areas of a surface. Typically, such results are achieved by depositing a continuous film of the material and subsequently patterning the continuous film using lithography and etch steps. Such lithography and etch processes may be time consuming and expensive. Further, such processes may not provide the precision or resolution desired for many applications.

Recently, efforts have been made to develop selective deposition techniques to decrease a number of steps for patterning deposited material, reduce the cost of processing, and allow for formation of relatively small regions of selectively deposited material. While some selective deposition techniques may work relatively well, there is a general desire to develop improved selective deposition techniques that provide desired selectivity of deposited material and desired properties of the deposited material.

Any discussion of problems and solutions described in this section has been included in this disclosure solely for the purposes of providing a context for the present disclosure. Such should not be taken as an admission that any or all of the discussion is prior art or was known at the time the invention was made.

### SUMMARY OF THE DISCLOSURE

This summary is provided to introduce a selection of concepts that may be presented in a simplified form. Exemplary concepts are described in further detail in the detailed description below. This summary is not intended to necessarily identify key features or essential features of the claimed subject matter; nor is it necessarily intended to be used to limit the scope of the claimed subject matter.

As set forth in more detail below, various embodiments of the disclosure relate to methods of selectively depositing material on a surface or area of a substrate surface. Examples of the disclosure can be used to selectively deposit metal on a metal surface, relative to a non-metal or oxide surface. By way of particular examples, a method can be used to selectively deposit metal, such as molybdenum, on a copper surface.

Exemplary methods include providing a substrate comprising a first surface comprising copper and a second surface, performing a pre-deposition treatment process to activate the first surface, selectively treating the second surface to form a passivation layer on the second surface, and selectively depositing molybdenum material on the first surface to form selectively deposited molybdenum material. In accordance with examples of these embodiments, the second surface comprises insulating material, such as an oxide of a metal or metalloid. In accordance with aspects of these embodiments, the first surface comprises one or more of a copper metal or an oxide thereof. In accordance with further aspects, the method further includes a step of performing a post-deposition treatment process. The post-deposition treatment process can be configured to form treated molybdenum material and/or remove passivation layer material from the second surface. The performing the post-deposition treatment process can include forming activated species from a hydrogen-containing gas. In accordance with further aspects, the step of selectively depositing molybdenum material comprises a cyclical deposition process. The cyclical deposition process can include, for example, providing a pulse of a reducing agent, providing a pulse of a molybdenum precursor, and providing hydrogen. The reducing agent can be or include two-electron donor molecules. The step of providing hydrogen can be continuous through one or more cycles of the cyclical deposition process or continuous through the method. In accordance with further examples, a pressure within a reaction chamber during the providing the hydrogen before the providing a pulse of a reducing agent and the providing a pulse of a molybdenum precursor is higher than a pressure within the reaction chamber during the providing a pulse of a reducing agent and higher than a pressure within the reaction chamber during the providing a pulse of a molybdenum precursor. For example, the pressure within a reaction chamber during the providing the hydrogen before the providing a pulse of a reducing agent and the providing a pulse of a molybdenum precursor can be at least four times higher than the pressure within the reaction chamber during the providing a pulse of a reducing agent and/or than a pressure within the reaction chamber during the providing a pulse of a molybdenum precursor. In accordance with yet further examples, the pre-deposition treatment process includes forming activated species from a hydrogen-containing gas. In accordance with further aspects, the selectively treating the second surface includes providing an amino silane to a reaction chamber.

In accordance with additional embodiments, a reactor system is provided. Exemplary reactor systems include a reaction chamber, a molybdenum precursor source coupled to the reaction chamber, a reducing agent source, a hydrogen source, at least one passivation layer precursor source, and a controller. The controller can be configured to perform a pre-deposition treatment process, selectively treat the second surface to form a passivation layer on the second surface, and selectively deposit molybdenum material on the first surface to form selectively deposited molybdenum material and/or perform other steps as described herein. The reactor system can include a plurality of reaction chambers. One or more steps that are performed by the controller can be performed in one or more of the plurality of reaction chambers.

For the purpose of summarizing the invention and the advantages achieved over the prior art, certain objects and advantages of the invention may have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the disclosure. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWING FIGURES

A more complete understanding of the embodiments of the present disclosure may be derived by referring to the detailed description and claims when considered in connection with the following illustrative figures.

FIG. 1 illustrates a method in accordance with exemplary embodiments of the disclosure.

FIGS. 2-5 illustrate structures formed in accordance with examples of the disclosure.

FIG. 6 illustrates a schematic diagram of a reactor system in accordance with examples of the disclosure.

FIG. 7 illustrates a schematic diagram of a reactor system having multiple reaction chambers, in accordance with examples of the disclosure.

FIG. 8 illustrates another structure in accordance with examples of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure. The illustrations presented herein are not necessarily meant to be actual views of any particular material, structure, or system, but are merely representations that are used to describe embodiments of the disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As set forth in more detail below, various embodiments of the disclosure provide methods for selectively depositing material on one surface relative to another surface. Methods described herein can be used to form structures that can be used to, for example, form electronic devices, such as semiconductor devices, microelectromechanical devices, photonic devices, and the like.

As used herein, the term substrate can refer to any underlying material or materials that can be used to form, or upon which, a device, a circuit, or a film can be formed. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include semiconductor material. Exemplary substrates include a first surface of a first material and a second surface of a second material, wherein the first material and the second material are different. By way of particular example, the first material and/or first surface can be or include copper and/or an oxide thereof and the second material and/or second surface can be or include an insulating material, such as a dielectric material.

As used herein, a structure can be or include a substrate as described herein. Structures can include a substrate and one or more layers overlying the substrate, such as one or more layers formed by a method according to the current disclosure.

As used herein, the term film and/or layer can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may partially or wholly consist of a plurality of dispersed atoms on a surface of a substrate and/or embedded in a substrate and/or embedded in a device manufactured on that substrate. A film or layer may comprise material or a layer with pinholes and/or isolated islands.

As used herein, the term metallic surface may refer to surfaces including a metallic component, including, but not limited to, metal surfaces (e.g., elemental metal or a metal alloy), metal oxide surfaces, metal silicide surfaces, metal nitride surfaces, metal carbide surfaces, mixtures thereof, and the like. The term metallic surface may also include a surface of a native oxide of a metallic material.

As used herein, the term silicon surface or silicon-containing surface may refer to a surface that includes silicon and that may include additional elements. Exemplary silicon-containing materials include, for example, silicon, silicon oxides, silicon nitrides, silicon oxynitrides, silicon carbides, silicon oxycarbides, silicon carbon nitride, and mixtures thereof.

As used herein, an oxide surface can include a metal oxide or a metalloid oxide. Exemplary oxide surfaces include silicon oxides, metal oxides, silicon oxycarbides, and the like.

The term cyclic deposition process or cyclical deposition process can refer to the sequential introduction of precursors (and/or reactants) into a reaction chamber to deposit a layer over a substrate and includes processing techniques, such as atomic layer deposition (ALD), molecular layer deposition (MLD), cyclical chemical vapor deposition (cyclical CVD), and hybrid cyclical deposition processes that include an ALD component and a cyclical CVD component. In some cases, a cyclical deposition process can include continually flowing one or more precursors, reactants, or inert gases, and pulsing other of the precursors or reactants. The term MLD may refer to a vapor deposition process in which one or more deposition cycles are conducted in a process chamber. Typically, during each cycle an organic precursor is chemisorbed to a deposition surface (e.g., a substrate surface or a previously deposited underlying surface, such as material from a previous MLD cycle), typically forming a single molecular layer that does not readily react with additional organic precursor (i.e., a self-limiting reaction). Thereafter, if desired, another precursor (e.g., another organic precursor) may subsequently be introduced into the process chamber for use in forming the desired organic material on the deposition surface. Further, purging steps may also be utilized during each cycle to remove excess organic precursor from the process chamber and/or remove reaction byproducts from the process chamber after formation of the desired organic material.

As used herein, the term purge can refer to a procedure in which an inert or substantially inert gas is provided to a reaction chamber in between two pulses of gases that might otherwise react with each other. For example, a purge, e.g., using an inert gas, such as a noble gas, may be provided between a precursor pulse and a reactant pulse to reduce gas phase interactions between the precursor and the reactant that might otherwise occur. It shall be understood that a purge can be effected either in time or in space, or both. For example, in the case of temporal purges, a purge step can be used, e.g., in the temporal sequence of providing a precursor to a reaction chamber, providing a purge gas to the reaction chamber, and providing a reactant or another precursor to the reaction chamber, wherein the substrate on which a layer is deposited does not move. In the case of spatial purges, a purge step can take the following form: moving a substrate from a first location to which a precursor is (e.g., continually) supplied, through a purge gas curtain, to a second location to which a reactant or other precursor is (e.g., continually) supplied.

In this disclosure, continuously or continuous can refer to without breaking a vacuum, without interruption as a timeline, without any material intervening step, without changing treatment conditions, immediately thereafter, as a next step, or without an intervening discrete physical or chemical structure between two structures other than the two structures in some embodiments and depending on the context.

Further, in this disclosure, any two numbers of a variable can constitute a workable range of the variable, and any ranges indicated may include or exclude the endpoints. Additionally, any values of variables indicated (regardless of whether they are indicated with the term about or not) may refer to precise values or approximate values and include equivalents, and may refer to average, median, representative, majority, or the like. For example, the term about can refer to +/−20, 10, 5, 2, or 1 percent of a value. The terms comprising, including, constituted by and having refer independently to typically or broadly comprising, comprising, consisting essentially of, or consisting of in some embodiments. In this disclosure, any defined meanings do not necessarily exclude ordinary and customary meanings, in some embodiments.

Although a number of example materials are given throughout the embodiments of the current disclosure, it should be noted that the chemical formulas given for each of the example materials should not be construed as limiting and that the non-limiting example materials given should not be limited by a given example stoichiometry.

As noted above, various examples of the disclosure relate to selectively forming material on one surface relative to another surface. Selectivity of forming or deposing material can refer to a relatively higher amount of material formed or deposited on a surface relative to another surface. For example, selectivity of deposition on surface A relative to surface B can be given as a percentage calculated by [(deposition on surface A)−(deposition on surface B)]/(deposition on the surface A). Deposition can be measured in any of a variety of ways. For example, deposition may be given as the measured thickness of the deposited material or as the measured amount (e.g., weight) of material deposited.

As set forth in more detail below, in embodiments described herein, selective deposition of a passivation layer can be conducted on a second surface (B) relative to a first surface (A). Subsequently, a first material may be selectively deposited on the first surface (A) relative to the passivation layer (B). In some embodiments, selectivity is greater than about 10%, or greater than about 50%, or greater than about 75%, or greater than about 85%, or greater than about 90%, or greater than about 93%, or greater than about 95%, or greater than about 98%, or greater than about 99%, or even greater than about 99.5%.

In some embodiments, deposition only occurs on one surface and does not occur on the other surface. It will be appreciated that a partially selective process can result in a fully selective structure by, for example, a post-deposition treatment.

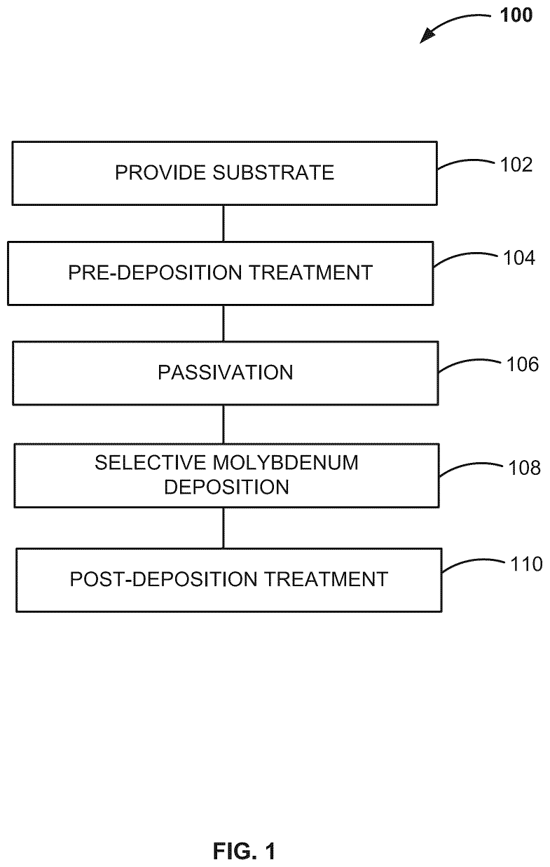

Turning now to the figures, FIG. 1 illustrates a method 100 of selectively depositing a material on a surface of a substrate in accordance with embodiments of the disclosure. Method 100 includes the steps of providing a substrate within a reaction chamber of a reactor (102), performing a pre-deposition treatment process (104), selectively treating (passivating) the second surface (106), selectively depositing molybdenum material (108), and (optionally) performing a post-deposition treatment process (110).

During step 102, a substrate is provided within a reaction chamber. The reaction chamber can be a standalone reaction chamber or part of a cluster tool, such as a cluster tool described in more detail below. The reaction chamber can include a substrate heater to heat a substrate to a temperature noted herein. Additionally or alternatively, the reaction chamber can include rapid thermal processing apparatus, such as lamps, to heat the substrate.

The reaction chamber may be configured for performing all, or a portion, of the steps of method 100. In some embodiments of the disclosure, a first reaction chamber may be configured to perform one or more steps of method 100 and further reaction chamber(s) may be employed for other steps of method 100. However, in additional embodiments of the disclosure, the first reaction chamber may be configured to perform all of the steps of method 100.

Reactors and associated reaction chamber(s) capable of performing one or more steps of method 100 include atomic/molecular layer deposition (ALD/MLD) reaction chambers, plasma enhanced atomic layer deposition (PEALD) reaction chambers, as well as chemical vapor deposition (CVD) reaction chambers equipped with appropriate equipment and means for providing precursors. According to some embodiments, a showerhead reaction chamber may be used. According to some embodiments, a plasma reaction chamber, such as a PEALD reaction chamber, may be used. In such embodiments, the plasma may be direct, remote, or in near vicinity of the substrate. In some embodiments, the reactor is a spatial ALD reactor, in which the substrate moves or rotates during processing. In some cases, the reactor is a thermal reactor.

In some embodiments, a batch reactor may be used. In some embodiments, a vertical batch reactor is utilized in which the boat rotates during processing. For example, a vertical batch reactor may comprise a reaction chamber and an elevator constructed and arranged to move a boat configured for supporting a batch of between 10 to 200 substrates in or out of the reaction chamber.

In other embodiments, the batch reactor comprises a mini-batch reactor configured to accommodate 10 or fewer wafers, 8 or fewer wafers, 6 or fewer wafers, 4 or fewer wafers, or 2 wafers. In some embodiments in which a batch reactor is used, wafer-to-wafer non-uniformity is less than 3% (1sigma), less than 2%, less than 1% or even less than 0.5%.

Method 100 can optionally be carried out in a reactor and associated reaction chambers that form a cluster tool. In a cluster tool, each reaction chamber may be dedicated to one type of process, such that, for example, a temperature of the reaction chamber in each module can be kept constant, which can improve the throughput, compared to a reaction chamber in which the substrate is heated up to the process temperature before each run. Additionally, in a cluster tool, it is possible to reduce the time to pump the reaction space to the desired process pressure levels between substrates. In some embodiments of the disclosure, a stand-alone reactor can be equipped with a load-lock. In that case, it may not be necessary to cool down the reaction space between each run.

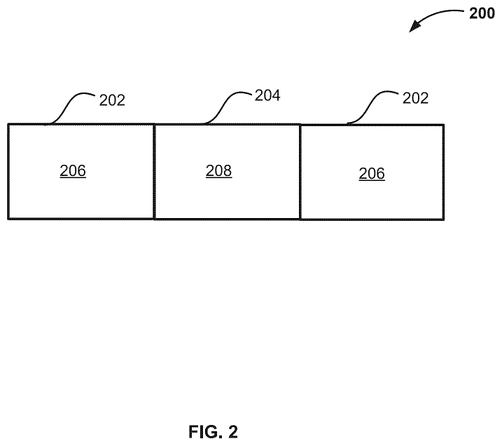

FIG. 2 illustrates a substrate 200 that can be supplied during step 102. Substate 200 provided during step 102 can include a first surface 202 and a second surface 204. First surface 202 can include a first material 206 and second surface 204 can include a second material 208 different than first material 206. For example, first surface 202 can be or include a metal, such as copper. In some cases, first material 206 or first surface 202 is a metallic surface. In some cases, the first surface can include a plurality of metal-containing materials. For example, the first surface can include a liner or barrier layer material and a fill material, such as a metal (e.g., copper) or metal alloy.

Second surface 204 and/or second material 208 can be or include silicon. By way of examples, second surface 204 can be or include silicon, a silicon surface having native oxide (also a form of silicon oxide) formed thereover, SiCHO, SiOₓ, SiO₂, SiC, SiOC, SiCN, SiON, SiOCN, SiGe, or the like or a combination thereof. Additionally or alternatively, second surface and/or second material can be or include an insulating material such as a dielectric material. The dielectric material can be a relatively low dielectric constant material, such as silicon oxide or the like, or can be a high dielectric constant material, such as a (e.g., transition) metal oxide, such as hafnium oxide or the like.

Once the substrate has been loaded into a suitable reaction chamber, the substrate may be heated to a suitable temperature—e.g., for a degas or for subsequent step 104. By way of examples, the substrate can be heated to a temperature of about 150° C. to about 250°C. or about 250° C. to about 400° C. A pressure within the reaction chamber during step 102 can be between about 100 mTorr and 1 Torr, or between 200 mTorr and 800 mTorr.

During step 104, a pre-deposition treatment process to activate the first surface is performed. Pre-deposition treatment process step 104 can include, for example, exposing a surface of the substrate to a hydrogen-containing gas. For example, step 104 can include forming activated species from a hydrogen-containing gas. The hydrogen-containing gas can be or include hydrogen (H₂). The hydrogen-containing gas can be provided alone, or in combination with another gas, such as a purge or a carrier gas. In some cases, the hydrogen-containing gas can be provided to the reaction chamber with an inert gas, such as argon. In accordance with examples, a nitrogen-containing gas is not provided to the reaction chamber during step 104. In accordance with further examples, activated species provided during step 104 can be formed using direct, indirect, or a remote plasma. In some cases, a remote plasma or indirect plasma may be preferred. A temperature during step 104 can be as described above in connection with step 102. A pressure within the reaction chamber during step 104 can be between about 1 and about 5 or about 5 and about 10 Torr.

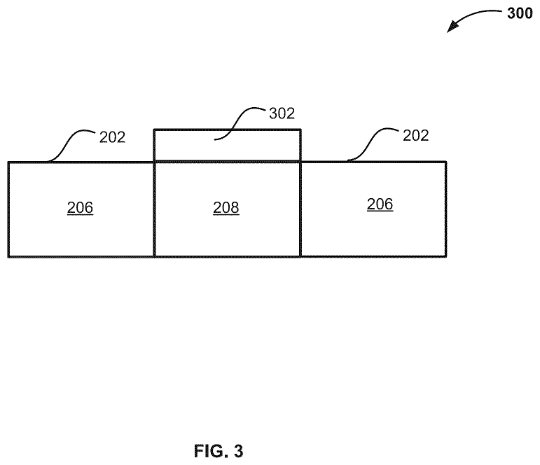

During step 106, the second surface is selectively treated to form a passivation layer on the second surface. FIG. 3 illustrates a structure 300 including a passivation layer 302 overlying second surface 204.

In accordance with examples of the disclosure, the passivation material is or includes a polymer or a small molecule inhibitor. In accordance with additional examples, the passivation material is or includes organic material.

Various precursors and reactants can be used to deposit the passivation material. Exemplary passivation material precursors and/or reactants include polyimide precursors, SAM precursors, small molecule inhibitor precursors, and area selective deposition precursors. In some cases, the passivation material is selectively deposited using a passivation material precursor, such as small molecule inhibitor precursors.

Exemplary small molecule inhibitor precursors include a silylating agent and/or an amino silane. A silylating agent/amino silane according to the current disclosure can be provided in a vapor phase. In some embodiments, a silylating agent/amino silane comprises one or more of (N, N-dimethylamino)trimethylsilane, allyltrimethylsilane, bis(dimethylamino)dimethylsilane, bis(dimethylamino)diethylsilane, halosilane, for example, chlorotrimethylsilane or octadecyltrichlorosilane, an imidazole, for example, N-(trimethylsilyl)imidazole, a silazane, for example, hexamethyldisilazane, a silylamine, for example, N-(trimethylsilyl)dimethylamine or 1,1,1-trimethoxy-N, N-dimethylsilanamine or a pyrrole, such as 1-(triisopropylsilyl)pyrrole. The substrate may be contacted with a sufficient quantity of the passivating agent and for a sufficient period of time that the top surface is selectively blocked with silicon species.

A temperature within a reaction chamber during step 106 can be between about 100° C. and about 200° C. or between about 200° C. and about 400° C. A pressure within the reaction chamber can be between about 0 Torr and about 5 Torr or between about 5 Torr and about 20 Torr.

A thickness of the passivation layer (e.g., passivation layer 302) on the second surface 204 can be between about 0.1 nm and about 2.5 nm or between about 2.5 nm and about 7.5 nm. A selectivity of the first material deposited on the second surface relative to the first surface can be as described above.

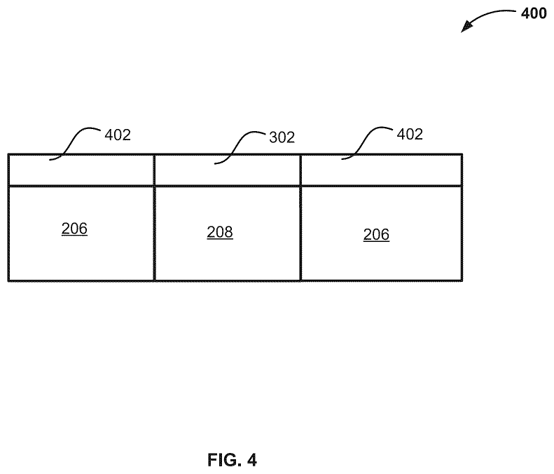

During step 108, a metal, such as molybdenum, is selectively deposited over first surface 202. FIG. 4 illustrates a structure 400, which includes metallic material (e.g., molybdenum) 402 formed overlying first material 206.

Step 108 of selectively depositing molybdenum material on the first surface relative to the second surface can include a cyclical deposition process. Step 108 can include providing a metal precursor providing a reducing agent and providing hydrogen (H₂). Such steps can be separated by a purge step. In some cases, the cyclical deposition process includes providing a pulse of a reducing agent, providing a pulse of a molybdenum precursor, and providing hydrogen, wherein the reducing agent is different than hydrogen. A duration of a pulse can be between, for example, about 0.5 ms to about 60 seconds or about 0.5 ms to about 10 seconds. In some cases, the hydrogen can also be pulsed to the reaction chamber. For example, the hydrogen can be pulsed between the steps of providing the pulse of a molybdenum precursor and providing a pulse of a reducing agent. In some cases, the step of providing hydrogen is continuous through one or more cycles of the cyclical deposition process—e.g., though one or more (e.g., all of) steps 104-110. In some cases, step 108 includes, in the following order: providing hydrogen, providing a pulse of a reducing agent, a first purge, providing a pulse of a molybdenum precursor, and a second purge. As above, the hydrogen can be provided continuously through the at least one cycle (e.g., all cycles and/or one or more (e.g., all) steps of method 100) and ceases after the second purge. In accordance with further examples, the at least one cycle or the cyclical deposition process includes providing the hydrogen before the providing a pulse of a reducing agent and the providing a pulse of a molybdenum precursor.

In accordance with further examples, a pressure within a reaction chamber can change to obtain deposited molybdenum with desired properties. For example, a pressure within a reaction chamber during the providing the hydrogen before the providing a pulse of a reducing agent and the providing a pulse of a molybdenum precursor can be higher than a pressure within the reaction chamber during the providing a pulse of a reducing agent and higher than a pressure within the reaction chamber during the providing a pulse of a molybdenum precursor. In some cases, the pressure within a reaction chamber during the providing the hydrogen before the providing a pulse of a reducing agent and the providing a pulse of a molybdenum precursor can be at least four times higher than the pressure within the reaction chamber during the providing a pulse of a reducing agent and/or than a pressure within the reaction chamber during the providing a pulse of a molybdenum precursor.

Exemplary metal precursors suitable for use in step 108 include a metal and one or more ligands. By way of examples, the ligands can include one or more of alkyls, alkoxides, diketonates, acetamidinates, formamidinates, guanidinates, amides, alkoxyamines, aryls, cyclopentadienyls, halogens. Particular exemplary metal precursors include metal halides and metal oxide halides, such as one or more of one or more of molybdenum tetrachloride (MoCl₄), molybdenum pentachloride (MoCl₅), molybdenum (V) trichloride oxide (MoOCl₃), molybdenum (VI) tetrachloride oxide (MoOCl₄), and/or molybdenum (IV) dichloride dioxide (MoO₂Cl₂).

Exemplary reducing agents suitable for use during step 108 include molecules that include two-electron donor or two-electron donor molecules. In some case, the reducing agent comprises molecules having a cyclical structure. In some cases, the reducing agent comprises a cyclohexadiene. In some cases, the reducing agent (e.g., the cyclical structure) includes at least one C1-C4 alkyl group thereon. In some cases, the reducing agent (e.g., the cyclical structure) includes one or more—e.g., two or more (e.g., C1-C4) alky lsilyl groups, such as trimethylsilyl groups. In some cases, the reducing agent comprises a molecule comprising two or more C—C double bonds and one or more alkyl silyl groups. By way of particular example, the reducing agent is or includes 1-methyl-2,5-di-trimethylsilyl cyclohexa-1,4-diene. After the selective molybdenum deposition step 108, the passivation step 106 may be repeated to allow for reapplication of the passivation material.

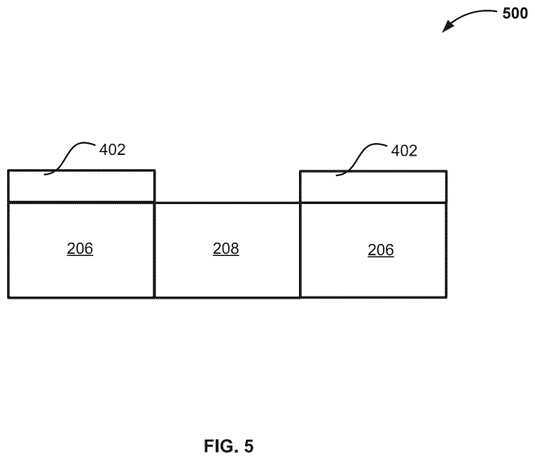

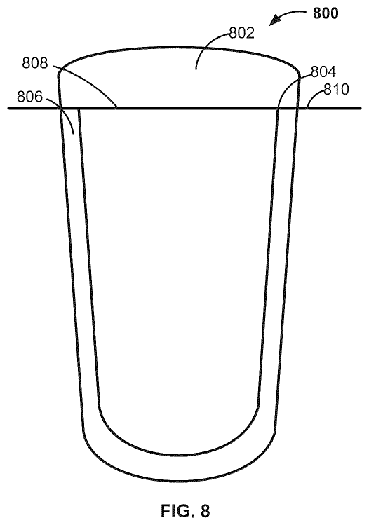

During post-deposition treatment step 110, treated molybdenum material can be formed and passivation layer material can be removed from the second surface. FIG. 5 illustrates a structure 500 with the passivation layer material removed. FIG. 8 illustrates another structure 800 that includes (e.g., treated) molybdenum 802 selectively formed overlying a first surface 804 that includes a barrier or liner layer 806 (e.g., a metal nitride or the like, such as TiN, TaN, MoN, Ru) and a bulk metallic surface 808, such as copper. A surface 810 can be any second surface material described herein.

Similar to step 104, post-deposition treatment process step 110 can include exposing a surface of the substrate to a hydrogen-containing gas. For example, step 110 can include forming activated species from a hydrogen-containing gas. The hydrogen-containing gas can be or include hydrogen (H₂). The hydrogen-containing gas can be provided alone, or in combination with another gas, such as a purge or a carrier gas. In some cases, the hydrogen-containing gas can be provided to the reaction chamber with an inert gas, such as argon. In accordance with further examples, activated species provided during step 110 can be formed using direct, indirect, or a remote plasma. In some cases, a remote plasma or indirect plasma may be preferred. A temperature and pressure within the reaction chamber during step 110 can be as described above in connection with step 104.

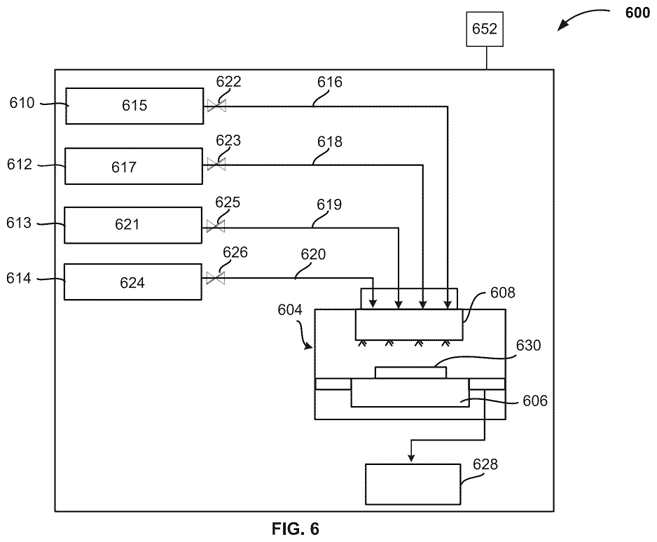

Referring now to FIG. 6, in various examples, a reactor system 600 includes a reaction chamber 604, a susceptor 606 to hold a substrate 630 during processing, a gas distribution system 608 (e.g., a showerhead) to distribute one or more precursors and/or reactants to a surface of substrate 630, one or more precursor or reactant sources 610, 612, and/or 613, and/or a carrier and/or purge gas source 614, fluidly coupled to reaction chamber 604 via respective lines 616, 618, 619 and 620, and respective valves or controllers 622, 623, 625 and 626. Substrate 630 can include a substrate or structure as described herein. A purge/carrier gas 624 from gas source 614 can be flowed to and through reaction chamber 604 to act as a carrier gas, and/or purge or remove any excess reactant or other undesired materials from reaction chamber 604. Sources 610, 612, and 613 can include vessels and a precursor or reactant as described herein. For example, source 610 can include a vessel and a metal precursor 615; source 612 can include a vessel and hydrogen 617; source 613 can include a vessel and a reducing agent 621. Reactor system 600 can include additional sources. Reactor system 600 can also include a vacuum source 628 fluidly coupled to the reaction chamber 604. Vacuum source 628 can be configured to evacuate reactants, a purge gas, or other materials out of reaction chamber 604.

Reactor system 600 also includes a controller 652. Controller 652 can be configured to perform various functions and/or steps as described herein. Controller 652 can include one or more microprocessors, memory elements, and/or switching elements to perform the various functions. Although illustrated as a single unit, controller 652 can alternatively comprise multiple devices. Controller 652 can be used to control gas flow (e.g., by monitoring flow rates and controlling valves 622, 623, 625 and/or 626), motors, heaters, cooling devices and/or vacuum source 628 to execute various processes (e.g., method 100). Further, when a system includes two or more reaction chambers, as described in more detail below, the two or more reaction chambers can be coupled to the same/shared controller.

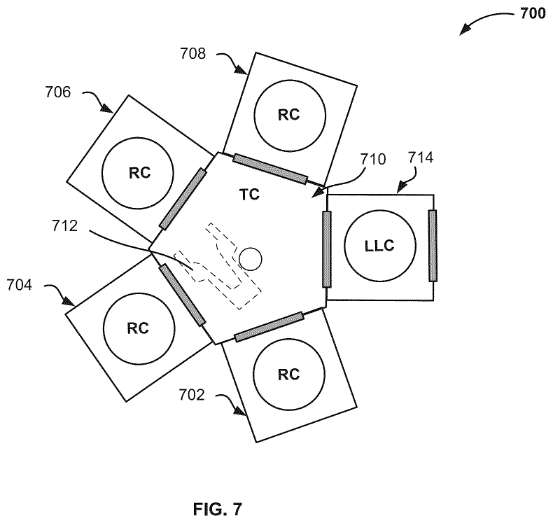

FIG. 7 illustrates a reactor system 700 that includes a plurality of reaction chambers 702-708, each of which can be an example of reaction chamber 604 in FIG. 6. Reaction chambers 702-708 can be disposed around and/or coupled to a transfer chamber 710 that includes a transfer tool 712 for transferring substrates between reaction chambers 702-708 and a load lock chamber 714 and between reaction chambers 702-708 (e.g., through transfer chamber 710). For example, a substrate 630 can be disposed in different chambers for different steps of a method described herein. For example, one of reaction chambers 702-708 can be used to form a passivation layer as described herein, another one of reaction chambers 702-708 can be used to selectively deposit a molybdenum, another one of reaction chambers 702-708 can be used for pre-treatment, and another one of reaction chambers 702-708 can be used for post-treatment as described herein. Other configurations are also possible, such that one or more steps of method 100 or 800 are performed within a single reaction chamber.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method of selectively depositing material on a surface of a substrate, the method comprising the steps of:
providing a substrate comprising a first surface comprising copper and a second surface;
performing a pre-deposition treatment process to activate the first surface;
selectively treating the second surface to form a passivation layer on the second surface; and
selectively depositing molybdenum material on the first surface to form selectively deposited molybdenum material.

2. The method of claim 1, wherein the first surface comprises one or more of a copper metal or an oxide thereof.

3. The method of claim 1, further comprising a step of performing a post-deposition treatment process to form treated molybdenum material and remove passivation layer material from the second surface.

4. The method of claim 3, wherein the performing the post-deposition treatment process comprises forming activated species from a hydrogen-containing gas.

5. The method of claim 1, wherein the step of selectively depositing molybdenum material comprises a cyclical deposition process.

6. The method of claim 5, wherein at least one cycle of the cyclical deposition process comprises:
providing a pulse of a reducing agent;
providing a pulse of a molybdenum precursor; and
providing hydrogen.

7. The method of claim 6, wherein the molybdenum precursor comprises one or more of molybdenum tetrachloride (MoCl₄), molybdenum pentachloride (MoCl₅), molybdenum (V) trichloride oxide (MoOCl₃), molybdenum (VI) tetrachloride oxide (MoOCl₄), or molybdenum (IV) dichloride dioxide (MoO₂Cl₂).

8. The method of claim 6, wherein the reducing agent comprises two-electron donor molecules.

9. The method of claim 6, wherein the reducing agent comprises a cyclical structure.

10. The method of claim 6, wherein the reducing agent comprises a molecule comprising two or more C-C double bonds and one or more alkyl silyl groups.

11. The method of claim 6, wherein the reducing agent comprises 1-methyl-2,5-di-trimethylsilyl cyclohexa-1,4-diene.

12. The method of claim 6, wherein the step of providing hydrogen is continuous through one or more cycles of the cyclical deposition process.

13. The method of claim 6, wherein the at least one cycle comprises the providing the hydrogen before the providing a pulse of a reducing agent and the providing a pulse of a molybdenum precursor.

14. The method of claim 13, wherein a pressure within a reaction chamber during the providing the hydrogen before the providing a pulse of a reducing agent and the providing a pulse of a molybdenum precursor is higher than a pressure within the reaction chamber during the providing a pulse of a reducing agent and higher than a pressure within the reaction chamber during the providing a pulse of a molybdenum precursor.

15. The method of claim 14, wherein the pressure within a reaction chamber during the providing the hydrogen before the providing a pulse of a reducing agent and the providing a pulse of a molybdenum precursor is at least four times higher than the pressure within the reaction chamber during the providing a pulse of a reducing agent and higher than a pressure within the reaction chamber during the providing a pulse of a molybdenum precursor.

16. The method of claim 6, wherein the at least one cycle comprises, in the following order:
providing hydrogen;
providing a pulse of a reducing agent;
a first purge;
providing a pulse of a molybdenum precursor; and
a second purge.

17. The method of claim 16, wherein the providing the hydrogen is continuous through the at least one cycle and ceases after the second purge.

18. The method of claim 1, wherein the pre-deposition treatment process comprises forming activated species from a hydrogen-containing gas.

19. The method of claim 1, wherein the selectively treating the second surface comprises providing an amino silane to a reaction chamber.

20. The method of claim 1, wherein the second surface comprises insulating material.
